(19) United States
(12) Patent Application Publication
(10) Pub. No.: US 2024/0195302 A1
(43) Pub. Date: Jun. 13, 2024

(54) H-BRIDGE CIRCUIT FOR ENERGIZING AN INDUCTOR

(71) Applicant: Robert Bosch GmbH, Stuttgart (DE)

(72) Inventor: Matthias Schneider, Korntal-Muenchingen (DE)

(21) Appl. No.: 18/526,554

(22) Filed: Dec. 1, 2023

(30) Foreign Application Priority Data
Dec. 8, 2022 (DE) 10 2022 213 311.0

(51) Int. Cl. H02M 3/158; H01F 7/06

(52) U.S. Cl. CPC H02M 3/158; H01F 7/064

(57) ABSTRACT

An H-bridge circuit for energizing an inductor. The H-bridge circuit has four switches. A freewheeling diode is connected in parallel with each switch.

### CROSS REFERENCE

The present application claims the benefit under 35 U.S.C. § 119 of German Patent Application No. DE 10 2022 213 311.0 filed on Dec. 8, 2022, which is expressly incorporated herein by reference in its entirety.

### FIELD

The present invention relates to an H-bridge circuit for energizing an inductor.

### BACKGROUND INFORMATION

In motor vehicles, actuators are often used which are operated using a simple DC motor.

The energization of the actuator or motor frequently takes place via switches having freewheeling diodes which are arranged as an H bridge or in a simpler arrangement. The simplest arrangement requires a switch connected to the voltage supply and a freewheeling diode connected to ground. In the following, an inductor is considered to be representative of the actuator or the motor. During operation, short circuits to the battery supply or to ground (GND) can occur at the inductor, which must be detected.

For the diagnosis of the connections of the inductor, as related art, the voltages at the inductor are considered as a function of the state of the switches. Hard short-circuits to the battery supply or to GND can thus be detected. Soft short-circuits are considerably more difficult to diagnose.

### SUMMARY

An advantage of the present invention is the detection of an incorrect energization of an actuator or motor and the plausibility check on current measurement. The reason for the incorrect energization can be a short-circuit at the actuator/motor or an incorrect current measurement.

According to an example embodiment of the present invention, in order to detect short circuits of this kind, a circuit arrangement comprising measuring arrangements M1, M2, and M3, measuring resistors SH1 and SH2, and resistors R1, R2 and R3 is provided. R1 relates to a positive reference voltage. R2 and R3 have the same resistance value. The resistance values of the resistors R1, R2, and R3 are significantly higher than the resistance values of the measuring resistors SH1 and SH2.

A measuring arrangement is used to measure in the freewheeling mode whether there is a difference between the currents flowing through SH1 and SH2. This case occurs when a resistor SG1, SG2, SB1, SB2 becomes less resistive. An incorrect energization of the inductor can thus be detected.

### BRIEF DESCRIPTION OF THE DRAWING

FIG. 1 shows a circuit according to an example embodiment of the present invention.

### DETAILED DESCRIPTION OF EXAMPLE EMBODIMENTS

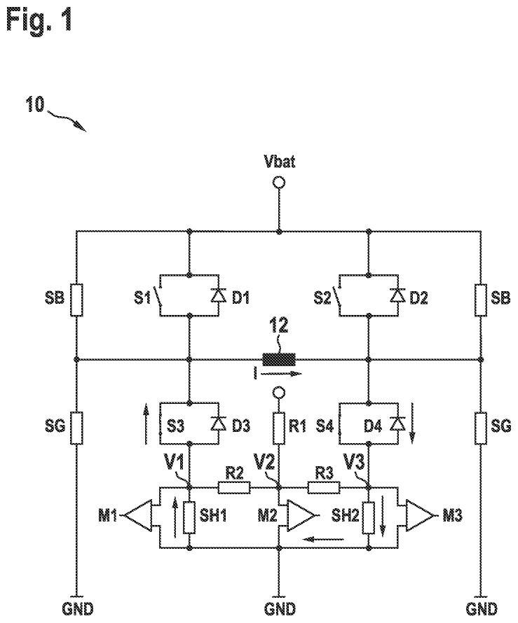

FIG. 1 shows an H-bridge circuit 10 for energizing an inductor 12. The H bridge 10 has four switches S1, S2, S3, S4. A freewheeling diode D1, D2, D3, D4 is connected in parallel with each switch S1, S2, S3, S4. The current flowing through the inductor 12 increases when the switches S1, S4 are switched on and the switches S2, S3 are switched off. If, in the freewheeling mode, the switches S1, S2 are switched off and the switches S3, S4 are switched on, the current flowing through the inductor 12 is reduced.

The electrical current runs according to the indicated arrows. M1, M2, and M3 represent measuring arrangements. SH1 and SH2 are measuring resistors. The current is measured with the measuring arrangements M1 and M3 and the measuring resistors SH1 and SH2. M1 is arranged in parallel with SH1 between the switch S3 (node V1) and GND. M2 is arranged in parallel with SH1 and SH2 between the node V2 and GND. M3 is arranged in parallel with SH2 between the switch S3 (node V3) and GND. SG1 and SG2 are short-circuit resistances which are connected to ground GND. SB1 and SB2 are short-circuit resistances which are connected to battery voltage Vbat.

The circuit 10 furthermore has resistors R1, R2, R3. R1 refers to a positive reference voltage. R2 and R3 have the same resistance value. The resistance values of the resistors R1, R2, and R3 are significantly higher than the resistance values of the measuring resistors SH1 and SH2.

If there is no short-circuit, the resistors SG1, SG2, SB1, SB2 will be high-impedance. In this case, the directions of the currents flowing through SH1 and SH2 are opposite. The values of the currents differ in their polarity sign.

The voltage at the node V3 is positive. The voltage at the node V1 is negative. The voltage V3 can be measured with the measuring arrangement M3. Via the dimensioning of the resistors R1, R2 and R3, whose values are significantly higher than the resistance value of the measuring resistors, a positive voltage can be set at V2 which corresponds to the difference of the currents which are measured with SH1 and SH2. R1 refers to a positive reference voltage. R2 and R3 have the same resistance value. The voltage at V2 remains constant during the freewheeling mode, as long as the same current flows via SH1 and SH2 but for different polarity signs and the tolerances of the components are disregarded. The measuring arrangement M2 is used to measure in freewheeling mode whether there is a difference between the currents flowing through SH1 and SH2. This case occurs when a resistor SG1, SG2, SB1, SB2 becomes less resistive. An incorrect energization of the inductor can thus be detected.

Alternatively, a comparison of the measured values from M3 and

M1 would be possible. Apart from the negative voltage at V1, the measurement values must be determined synchronously in the comparison. By contrast, the measurement via M2 enables the direct comparison of the currents flowing through SH1 and SH2.

The measuring arrangement M3 can be checked for plausibility with the measuring arrangement M2. The necessary condition for this is that the measuring arrangements operate independently of one another.

If an error should occur in the measuring arrangement M3, an incorrect energization of the inductor will be detected.

In an integrated circuit, measuring arrangements M1 and M3 are also possible, which can digitally detect and add up the currents in both directions with polarity signs. In the freewheeling mode, the added value should deviate from 0 if a short-circuit occurs at the inductor.

What is claimed is:

1. An H-bridge circuit for energizing an inductor, comprising:
four switches; and
freewheeling diodiodes, wherein a respective freewheeling diode of the freewheeling diodes is connected in parallel with each respective switch of the switches.

2. The H-bridge circuit according to claim 1, further comprising:
measuring arrangements, measuring resistors, and resistors, wherein a first resistor of the resisters relating to a positive reference voltage, and a second and third resistor of the resistors having the same resistance value.

3. The H-bridge circuit according to claim 2, further comprising:
short-circuit resistors, two of the short-circuit resistors being connected to ground, and two of the short-circuit resistors being connected to a battery voltage.

4. The H-bridge circuit according to claim 3, wherein resistance values of the resistors are significantly higher than resistance values of the measuring resistors.

5. The H-bridge circuit according to claim 3, wherein the short-circuit resistors are high-impedance when there is no short-circuit, and wherein directions of currents flowing through the measuring resistors differing in their polarity sign.

6. The H-bridge circuit according to claim 3, wherein a measuring arrangement of the measuring arrangements is used to measure, in a freewheeling mode, whether there is a difference between the currents flowing through the measuring resisters, in which case at least one of the short circuit resistors becoming less resistive.
